(19) United States
(12) Patent Application Publication
(10) Pub. No.: US 2026/0247709 A1
(43) Pub. Date: Aug. 20, 2026

(54) DRIVE CIRCUIT SUBSTRATE AND MANUFACTURING METHOD OF DRIVE CIRCUIT SUBSTRATE

(71) Applicant: SHARP KABUSHIKI KAISHA, Osaka (JP)

(72) Inventors: Tadayoshi Miyamoto, Osaka (JP); Naoki Makita, Osaka (JP)

(21) Appl. No.: 19/265,154

(22) Filed: Jul. 10, 2025

(30) Foreign Application Priority Data
Feb. 14, 2025 (JP) 2025-022666

(51) Int. Cl. H10D 86/40; H10D 86/01; H10D 86/60

(52) U.S. Cl. CPC H10D 86/421; H10D 86/0221; H10D 86/60; H10D 86/481

(57) ABSTRACT

A drive circuit substrate of the disclosure includes a first transistor provided with a first semiconductor layer having an island shape, a first insulating layer provided on the first semiconductor layer, a first gate electrode-cum-second counter electrode provided on the first insulating layer so as to overlap the first channel region and a part of the first source region serving as a first counter electrode in a plan view, a first drain electrode electrically connected to the first drain region, a first source electrode electrically connected to the first source region, and a holding capacitor including the first counter electrode and the second counter electrode, and the drive circuit substrate is provided with a plurality of unit drive circuits each including the first transistor.

### TECHNICAL FIELD

The disclosure relates to a drive circuit substrate and a manufacturing method of the drive circuit substrate.

### BACKGROUND

In recent years, unit drive circuits provided on a drive circuit substrate and each including a transistor have been widely used in the field of display devices as pixel circuits which display images in the display region of a display device or as driving drivers which are provided in the non-display region of a display device and which drive the pixel circuits. Unit drive circuits can also be applied to various fields outside of the display device field, such as those of 3D printers and fingerprint sensors. Therefore, research and development of unit drive circuits have been actively pursued.

### CITATION LIST

Patent Literature 1: US 2015/0055051 A
Patent Literature 2: US 2015/0053935 A

### SUMMARY

Patent Literatures 1 and 2 disclose that a drive circuit substrate, which includes a plurality of unit drive circuits each including a drive transistor and a selecting transistor, is used as a pixel circuit for displaying images on the display region of a display device.

In the field of display devices, there is a demand for higher definition of unit drive circuits on the drive circuit substrate in order to achieve improved image quality.

However, neither Patent Literature 1 nor 2 discloses a configuration or a method for making the unit drive circuit included in the drive circuit substrate high definition.

It is an object of an aspect of the disclosure to provide a drive circuit substrate and a manufacturing method of the drive circuit substrate that can make a unit drive circuit high definition.

In order to achieve the above object, a drive circuit substrate of the disclosure includes
a first transistor including
a first semiconductor layer having an island shape including a first channel region, and a first source region and a first drain region each containing an impurity,
a first insulating layer provided on the first semiconductor layer,
a first gate electrode-cum-second counter electrode provided on the first insulating layer so as to overlap the first channel region and a part of the first source region serving as a first counter electrode in a plan view,
a first drain electrode electrically connected to the first drain region,
a first source electrode electrically connected to the first source region; and
a holding capacitor including the first counter electrode and the second counter electrode.

The drive circuit substrate includes a plurality of unit drive circuits each including the first transistor.

In order to achieve the above object, a manufacturing method of a drive circuit substrate according to the disclosure includes
forming a first semiconductor layer having an island shape included in a first transistor provided with a holding capacitor including a first counter electrode and a second counter electrode,
forming a first insulating layer on the first semiconductor layer,
forming a first channel region, and a first source region and a first drain region each having an impurity concentration higher than an impurity concentration of the first channel region by forming a resist film having a predetermined shape on the first insulating layer and injecting an impurity into a part of the first semiconductor layer by using the resist film as a mask,
forming a first gate electrode-cum-second counter electrode on the first insulating layer to overlap the first channel region and a part of the first source region serving as the first counter electrode in a plan view after removing the resist film, and
forming a first drain electrode electrically connected to the first drain region and a first source electrode electrically connected to the first source region.

In the manufacturing method, a plurality of unit drive circuits including the first transistor are formed.

According to an aspect of the disclosure, a drive circuit substrate and a manufacturing method of the drive circuit substrate that can make a unit drive circuit high definition can be provided.

### BRIEF DESCRIPTION OF DRAWINGS

The disclosure will be described with reference to the accompanying drawings, wherein like numbers reference like elements.

FIG. 1 is a circuit diagram of a unit drive circuit provided on a drive circuit substrate according to a first embodiment.

FIG. 2 is a plan view illustrating a schematic configuration of the drive circuit substrate according to the first embodiment.

FIG. 3 is a cross-sectional view illustrating the schematic configuration of the drive circuit substrate according to the first embodiment.

FIG. 4 is a view illustrating some s of steps in a manufacturing method of the drive circuit substrate according to the first embodiment.

FIG. 5 is a view illustrating another some of steps in the manufacturing method of the drive circuit substrate according to the first embodiment.

FIG. 6 is a view illustrating still another some of steps in the manufacturing method of the drive circuit substrate according to the first embodiment.

FIG. 7 is a plan view illustrating a schematic configuration of a drive circuit substrate according to a first comparative example.

FIG. 8 is a cross-sectional view illustrating a schematic configuration of the drive circuit substrate according to the first comparative example.

FIG. 9 is a diagram illustrating a difference between the order of some of the steps in the manufacturing method of the drive circuit substrate according to the first embodiment and the order of some of the steps in the manufacturing method of the drive circuit substrate according to the first comparative example.

FIG. 10 is a plan view illustrating a schematic configuration of a drive circuit substrate according to a second embodiment.

FIG. 11 is a cross-sectional view illustrating the schematic configuration of the drive circuit substrate according to the second embodiment.

FIG. 12 is a view illustrating some of steps in a manufacturing method of the drive circuit substrate according to the second embodiment.

FIG. 13 is a view illustrating another some of steps in the manufacturing method of the drive circuit substrate according to the second embodiment.

FIG. 14 is a view illustrating still another some of steps in the manufacturing method of the drive circuit substrate according to the second embodiment.

FIG. 15 is a plan view illustrating a schematic configuration of a drive circuit substrate according to the third embodiment.

FIG. 16 is a cross-sectional view illustrating the schematic configuration of the drive circuit substrate according to the third embodiment.

FIG. 17 is a plan view illustrating a schematic configuration of a drive circuit substrate according to the fourth embodiment.

FIG. 18 is a cross-sectional view illustrating the schematic configuration of the drive circuit substrate according to the fourth embodiment.

FIG. 19 is a view illustrating a schematic manufacturing method of the drive circuit substrate according to the fourth embodiment.

### DESCRIPTION OF EMBODIMENTS

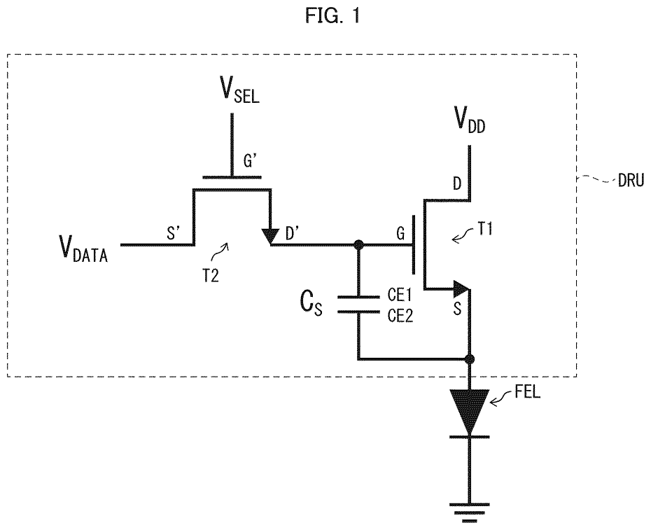

Embodiments of the disclosure will be described with reference to FIGS. 1 to 19 as follows. Hereinafter, for convenience of description, configurations having the same functions as those described in a specific embodiment are denoted by the same reference signs, and descriptions thereof will be omitted in some cases.

### First Embodiment

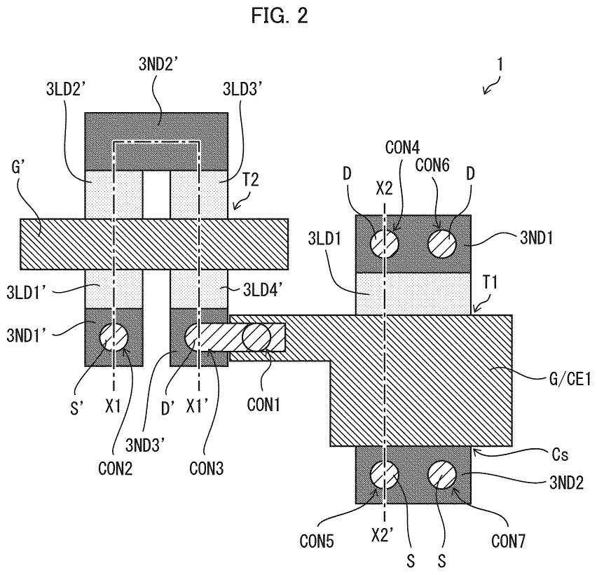

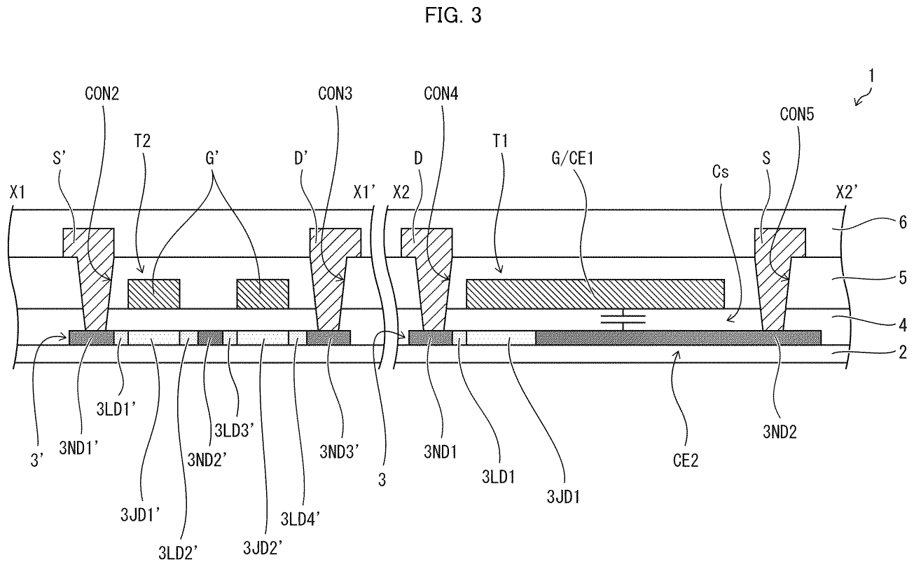

FIG. 1 is a circuit diagram of a unit drive circuit DRU provided on a drive circuit substrate 1 according to a first embodiment. FIG. 2 is a plan view of the drive circuit substrate 1 according to the first embodiment and is a view illustrating a schematic configuration of the drive circuit substrate 1. Note that, in FIG. 2, a barrier layer 2, a first insulating layer 4, a second insulating layer 5, and a passivation film 6 are not illustrated. FIG. 3 is a cross-sectional view illustrating the schematic configuration of the drive circuit substrate 1 according to the first embodiment. FIG. 3 is a cross-sectional view of the drive circuit substrate 1 taken along line X1-X1′ and line X2-X2′ illustrated in FIG. 2.

As illustrated in FIGS. 1, 2, and 3, each of the plurality of unit drive circuits DRU provided on the drive circuit substrate 1 includes a first transistor T1 provided with a holding capacitor Cs including a first counter electrode CE2 and a second counter electrode CE1. As illustrated in FIG. 3, the first transistor T1 provided with the holding capacitor Cs includes a first semiconductor layer 3 having an island shape, the first counter electrode CE2 serving as a part of the first semiconductor layer 3, the first insulating layer 4 provided on the first semiconductor layer 3, a first gate electrode G-cum-second counter electrode CE1 provided on the first insulating layer 4, a first drain electrode D, and a first source electrode S. The first semiconductor layer 3 having an island shape includes a first channel region 3JD1, and a first source region 3ND2 and a first drain region 3ND1 each containing an impurity. The first gate electrode G-cum-second counter electrode CE1 is provided on the first insulating layer 4 so as to overlap the first channel region 3JD1 and a part of the first source region 3ND2 serving as the first counter electrode CE2 in a plan view. The first drain electrode D is electrically connected to the first drain region 3ND1, and the first source electrode S is electrically connected to the first source region 3ND2.

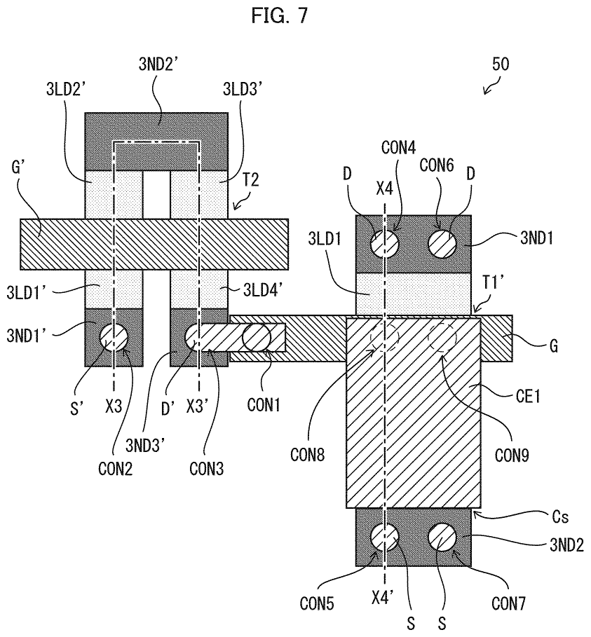

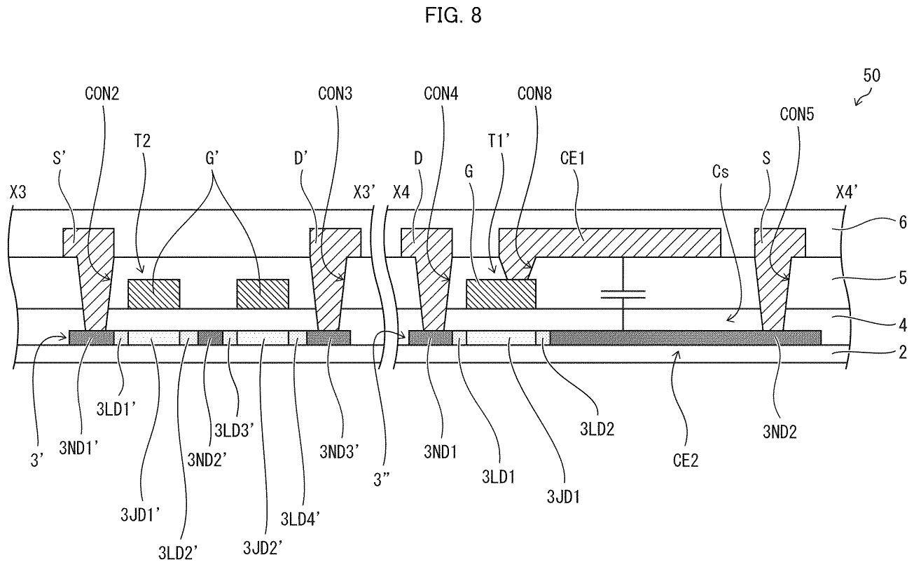

Since the first transistor T1 provided with the holding capacitor Cs included in each of the plurality of unit drive circuits DRU provided on the drive circuit substrate 1 is provided with the first gate electrode G-cum-second counter electrode CE1 as illustrated in FIGS. 2 and 3, it is not necessary to separately form a contact hole for electrically connecting the first gate electrode G and the second counter electrode CE1 to each other, and an area of the first transistor T1 can be reduced by not forming the contact hole. Thus, in the drive circuit substrate 1, the unit drive circuit DRU can be made high definition. On the other hand, in a case of a drive circuit substrate 50 including a first transistor T1′ provided with the holding capacitor Cs of the first comparative example including the first gate electrode G and the second counter electrode CE1 as different layers (see FIGS. 7 and 8), it is necessary to separately form contact holes CON8 and CON9 for electrically connecting the first gate electrode G and the second counter electrode CE1 to each other in the second insulating layer 5, and an area of the first transistor T1′ increases by formation the contact holes CON8 and CON9.

In the present embodiment, the first channel region 3JD1 is made of, for example, polysilicon that is a semiconductor containing no impurity, and each of the first source region 3ND2 and the first drain region 3ND1 each containing an impurity is formed by injecting an impurity into the polysilicon that is the semiconductor containing no impurity. In the present embodiment, each of the first source region 3ND2 and the first drain region 3ND1 each containing an impurity is formed by injecting phosphorus ion (P) that is an N-type impurity as an impurity, but is not limited thereto, and may be formed by injecting, for example, arsenic ion (As) that is an N-type impurity or may be formed by injecting boron ion (B) that is a P-type impurity.

In the present embodiment, as illustrated in FIG. 1, a case will be described as an example in which the unit drive circuit DRU includes the transistor T1 serving as a drive transistor, a transistor T2 serving as a selecting transistor, and the holding capacitor Cs. However, no such limitation is intended as long as the unit drive circuit DRU includes the first transistor T1 provided with the holding capacitor Cs.

In the present embodiment, each of the plurality of unit drive circuits DRU provided on the drive circuit substrate 1 includes the second transistor T2. As illustrated in FIG. 3, the second transistor T2 includes a second semiconductor layer 3′ having an island shape, the first insulating layer 4 provided on the second semiconductor layer 3′, and a second gate electrode G′, a second drain electrode D′ and a second source electrode S′ each provided on the first insulating layer 4. The second semiconductor layer 3′ having an island shape includes second channel regions 3JD1′ and 3JD2′, and a second source region 3ND1′ and a second drain region 3ND3′ each containing an impurity. The second gate electrode G′ is provided on the first insulating layer 4 so as to overlap the second channel regions 3JD1′ and 3JD2′ in a plan view. As illustrated in FIGS. 2 and 3, the second drain electrode D′ is electrically connected to the second drain region 3ND3′ and the first gate electrode G-cum-second counter electrode CE1, and the second source electrode S′ is electrically connected to the second source region 3ND1′.

In the present embodiment, each of the second channel regions 3JD1′ and 3JD2′ is made of polysilicon that is a semiconductor containing no impurity, similarly to the first channel region 3JD1, and each of the second source region 3ND1′ and the second drain region 3ND3′ is formed by injecting an impurity into the polysilicon that is the semiconductor containing no impurity, similarly to the first source region 3ND2 and the first drain region 3ND1 each containing an impurity. In the present embodiment, each of the second source region 3ND1′, a high concentration region 3ND2′, and the second drain region 3ND3′ each containing an impurity is formed by injecting phosphorus ion (P) that is an N-type impurity as an impurity, but is not limited thereto, and may be formed by injecting, for example, arsenic ion (As) that is an N-type impurity or may be formed by injecting boron ion (B) that is a P-type impurity.

As illustrated in FIG. 3, the first semiconductor layer 3 having an island shape and the second semiconductor layer 3′ having an island shape are provided on the barrier layer 2. The barrier layer 2 is a layer that prevents foreign matters, such as water and oxygen, from entering the first transistor T1 and the second transistor T2. For example, the barrier layer 2 can be formed of a silicon oxide film, a silicon nitride film, or a silicon oxynitride film, or a layered film thereof formed by chemical vapor deposition (CVD). A film thickness of the barrier layer 2 is not particularly limited as long as the barrier layer 2 can prevent foreign matters such as water and oxygen from entering the first transistor T1 and the second transistor T2.

In the present embodiment, a case will be described as an example in which each of the first semiconductor layer 3 having an island shape and the second semiconductor layer 3′ having an island shape is made of polysilicon formed at a low temperature and has a film thickness of 40 nm, but is not limited thereto, and may be made of, for example, an oxide semiconductor (for example, an In—Ga—Zn—O-based semiconductor) or may be made of polysilicon formed at a high temperature. Each of the first source region 3ND2 and the first drain region 3ND1 each containing an impurity in the first semiconductor layer 3 and each of the second source region 3ND1′ and the second drain region 3ND3′ each containing an impurity in the second semiconductor layer 3′ are regions formed by injecting an impurity into a semiconductor containing no impurity.

The first insulating layer 4 can be formed of, for example, a silicon oxide film, a silicon nitride film, or a silicon oxynitride film, or a layered film thereof, formed by CVD. In the present embodiment, a silicon nitride film having a film thickness of 85 nm is used as the first insulating layer 4.

The first gate electrode G-cum-second counter electrode CE1 of the first transistor T1 and the second gate electrode G′ of the second transistor T2 illustrated in FIG. 3 can be made of the same material as the same layer and can be formed of a single layer film or a layered film of a metal including, for example, at least one of aluminum, tungsten, molybdenum, tantalum, chromium, titanium, and copper. In the present embodiment, a MoW film which is an alloyed film of molybdenum and tungsten formed with a film thickness of 300 nm is used as each of the first gate electrode G-cum-second counter electrode CE1 and the second gate electrode G′.

In the present embodiment, as illustrated in FIG. 3, since the second drain electrode D′ of the second transistor T2 and the first gate electrode G-cum-second counter electrode CE1 of the first transistor T1 provided with the holding capacitor Cs are formed as different layers, the drive circuit substrate 1 includes the second insulating layer 5 provided so as to cover the first gate electrode G-cum-second counter electrode CE1 and the second gate electrode G′ in order to secure the insulating property between a layer forming the second drain electrode D′ of the second transistor T2 and a layer forming the first gate electrode G-cum-second counter electrode CE1 of the first transistor T1. The second insulating layer 5 can be formed of, for example, a silicon oxide film, a silicon nitride film, or a silicon oxynitride film, or a layered film thereof, formed by CVD. In the present embodiment, a layered film of a silicon oxide film formed with a film thickness of 680 nm and a silicon nitride film formed with a film thickness of 160 nm is used as the second insulating layer 5. As illustrated in FIG. 2, the second drain electrode D′ of the second transistor T2 and the first gate electrode G-cum-second counter electrode CE1 of the first transistor T1 provided with the holding capacitor Cs are electrically connected to each other via a contact hole CON1 formed in the second insulating layer 5.

The first drain electrode D and the first source electrode S of the first transistor T1 and the second drain electrode D′ and the second source electrode S′ of the second transistor T2 illustrated in FIG. 3 can be made of the same material as the same layer and can be formed of a single layer film or a layered film of a metal including, for example, at least one of aluminum, tungsten, molybdenum, tantalum, chromium, titanium, and copper. In the present embodiment, a layered film of titanium formed with a film thickness of 30 nm, aluminum formed with a film thickness of 300 nm, and titanium formed with a film thickness of 20 nm is used for each of the first drain electrode D, the first source electrode S, the second drain electrode D′, and the second source electrode S′.

As illustrated in FIG. 3, the drive circuit substrate 1 includes the passivation film 6 so as to cover the first drain electrode D, the first source electrode S, the second drain electrode D′, the second source electrode S′ and the second insulating layer 5. The passivation film 6 may be formed of, for example, a silicon oxide film, a silicon nitride film, or a silicon oxynitride film, or a layered film thereof, formed by CVD, and may be made of, for example, a coatable organic material such as polyimide or acrylic. In the present embodiment, a silicon nitride film with a film thickness of 300 nm is used as the passivation film 6.

In the present embodiment, as illustrated in FIGS. 2 and 3, a case will be described as an example in which the second transistor T2 is a double-gate transistor. However, no such limitation is intended, and the second transistor T2 may be a single-gate transistor. Since the second transistor T2 is the double-gate transistor, as illustrated in FIG. 3, the second transistor T2 includes the second semiconductor layer 3′ including two second channel regions 3JD1′ and 3JD2′ and two second gate electrode G′ overlapping the two second channel regions 3JD1′ and 3JD2′ in a plan view.

In the present embodiment, as illustrated in FIG. 3, since the second drain electrode D′ of the second transistor T2 and the first gate electrode G-cum-second counter electrode CE1 of the first transistor T1 provided with the holding capacitor Cs are formed as different layers, as illustrated in FIG. 2, the second drain electrode D′ of the second transistor T2 and the first gate electrode G-cum-second counter electrode CE1 of the first transistor T1 provided with the holding capacitor Cs are electrically connected to each other via the contact hole CON1 formed in the second insulating layer 5. No such limitation is intended, and as in a second embodiment described later, the second drain electrode D′ of the second transistor T2 and the first gate electrode G-cum-second counter electrode CE1 of the first transistor T1 provided with the holding capacitor Cs may be made of the same material as the same layer. Furthermore, as in the third embodiment described later, the second drain electrode D′ may be provided to contact the second drain region 3ND3′ via a contact hole CON3, and the first gate electrode G-cum-second counter electrode CE1 may be provided to contact the second drain region 3ND3′ via a contact hole.

In the present embodiment, as illustrated in FIG. 1, a case will be described as an example in which each unit drive circuit DRU includes a light-emitting element as a functional unit FEL electrically connected to the unit drive circuit DRU. However, no such limitation is intended, and for example, an anode electrode may be provided as the functional unit FEL electrically connected to the unit drive circuit DRU. In the present embodiment, a case will be described as an example in which the light-emitting element is an organic light-emitting diode (OLED). However, no such limitation is intended, and the light-emitting element may be a quantum dot light-emitting diode (QLED), for example. The functional unit FEL can be provided on, for example, the passivation film 6 illustrated in FIG. 3, and the functional unit FEL can be electrically connected to the first source electrode S of the first transistor T1 via a contact hole (not illustrated) formed in the passivation film 6.

The contact hole CON1 illustrated in FIGS. 2 and 3 is a contact hole formed in the second insulating layer 5, and contact holes CON2 to CON7 illustrated in FIGS. 2 and 3 are contact holes formed in the first insulating layer 4 and the second insulating layer 5.

As illustrated in FIG. 1, in the unit drive circuit DRU and the functional unit FEL, the first source electrode S of the first transistor T1 serving as the drive transistor is electrically connected to an electrode on one side of the light-emitting element serving as the functional unit FEL, for example, an anode electrode (not illustrated) and the first counter electrode CE2 of the holding capacitor Cs, the first gate electrode G of the first transistor T1 is electrically connected to the second counter electrode CE1 of the holding capacitor Cs and the second drain electrode D′ of the second transistor T2 serving as the selecting transistor, and the first drain electrode D of the first transistor T1 is electrically connected to a high potential side power supply voltage line VDD to which a high potential side power supply voltage is supplied. An electrode on the other side of the light-emitting element serving as the functional unit FEL, for example, a cathode electrode (not illustrated) is electrically connected to a low potential side power supply voltage line to which a low potential side power supply voltage is supplied, for example, a grounded low potential side power supply voltage line. The second source electrode S′ of the second transistor T2 serving as the selecting transistor is electrically connected to a data signal line VDATA to which a data signal is supplied, the second gate electrode G′ of the second transistor T2 is electrically connected to a scanning signal line VSEL to which a scanning signal is supplied, and the second drain electrode D′ of the second transistor T2 is electrically connected to the first gate electrode G of the first transistor T1 and the second counter electrode CE1 of the holding capacitor Cs. In the present embodiment, as illustrated in FIG. 1, since each unit drive circuit DRU includes a current-driven light-emitting element as the functional unit FEL electrically connected to the unit drive circuit DRU, the first transistor T1 included in each of the plurality of unit drive circuits DRU of the drive circuit substrate 1 preferably has a high current drive capability, and the current drive capability of the first transistor T1 is preferably stable. On the other hand, since the second transistor T2 supplies a voltage corresponding to the data signal to the first transistor T1 according to the timing of the scanning signal and changes a voltage of the first transistor T1, the second transistor T2 preferably has a transistor characteristic with a small leakage current.

In an NMOS transistor such as the first transistor T1 and the second transistor T2 described above, it is considered that electrons as carriers obtain a high kinetic energy in the channel region by a high electrical field to be accelerated and reach the highest speed near the drain region. Some of the electrons enter the first insulating film 4 with extra momentum, and further enter the first gate electrode G-cum-second counter electrode CE1 and the second gate electrode G′. In such a case, the electrical characteristics of the first transistor T1 and the second transistor T2 vary, and the drive capability of the first transistor T1 and the second transistor T2 is reduced.

Thus, in the present embodiment, a low concentration region lightly doped drain (LDD) is provided in each of the first semiconductor layer 3 provided in the first transistor T1 and the second semiconductor layer 3′ provided in the second transistor T2. The low concentration region LDD is a region formed by injecting ions having a lower concentration than the impurity concentrations of the source region and the drain region between the channel region and the source region and between the channel region and the drain region so as to be shallower than depths of the source region and the drain region. When electrons as carriers accelerated by obtaining the high kinetic energy reach the low concentration region LDD which is immediately before the drain and a low concentration portion of the impurity, the electrons are decelerated and their momentum is reduced, so that the electrons can be suppressed from entering the first gate electrode G-cum-second counter electrode CE1 and the second gate electrode G′. Here, since the NMOS transistor is used, the case of electrons has been described as an example, but in the PMOS transistor, it is necessary to adopt a configuration in which holes as carriers are suppressed from entering the first gate electrode G-cum-second counter electrode CE1 and the second gate electrode G′.

When the low concentration region LDD is provided for the purpose of electrical field relaxation, the same function can be maintained even when the low concentration region LDD is provided only on the drain region side. Thus, in the present embodiment, as illustrated in FIGS. 2 and 3, the first semiconductor layer 3 provided in the first transistor T1 includes the first channel region 3JD1, the first source region 3ND2, the first drain region 3ND1, and a first low concentration region 3LD1 provided between the first drain region 3ND1 and the first channel region 3JD1. However, no such limitation is intended. The first low concentration region 3LD1 contains an impurity and has an impurity concentration lower than that of each of the first source region 3ND2 and the first drain region 3ND1. The first gate electrode G and the second counter electrode CE1 do not overlap the first low concentration region 3LD1 in a plan view.

In the present embodiment, as illustrated in FIGS. 2 and 3, since the second transistor T2 is the double-gate transistor, a case will be described as an example in which the second semiconductor layer 3′ provided in the second transistor T2 includes the second channel regions 3JD1′ and 3JD2′, the second source region 3ND1′ containing an impurity at a high concentration, the high concentration region 3ND2′ containing an impurity at a high concentration, the second drain region 3ND3′ containing an impurity at a high concentration, and second low concentration regions 3LD1′, 3LD2′. 3LD3′, and 3LD4,′ each containing an impurity at a low concentration. The second low concentration region 3LD1′ is a region formed between the second channel region 3JD1′ and the second source region 3ND1′, the second low concentration region 3LD2′ is a region formed between the second channel region 3JD1′ and the high concentration region 3ND2′, the second low concentration region 3LD3′ is a region formed between the high concentration region 3ND2′ and the second channel region 3JD2′, and the second low concentration region 3LD4′ is a region formed between the second channel region 3JD2′ and the second drain region 3ND3′.

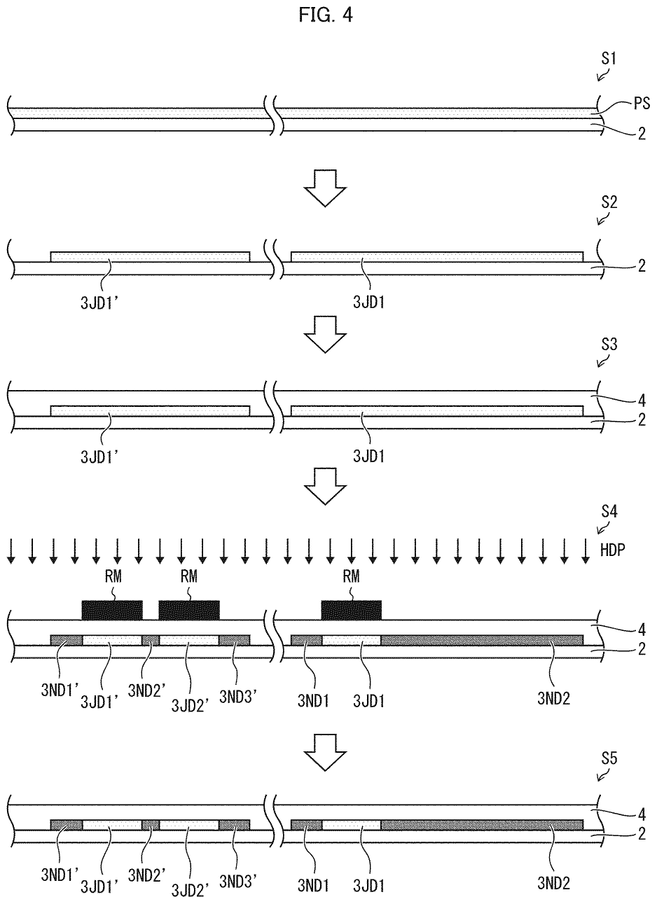

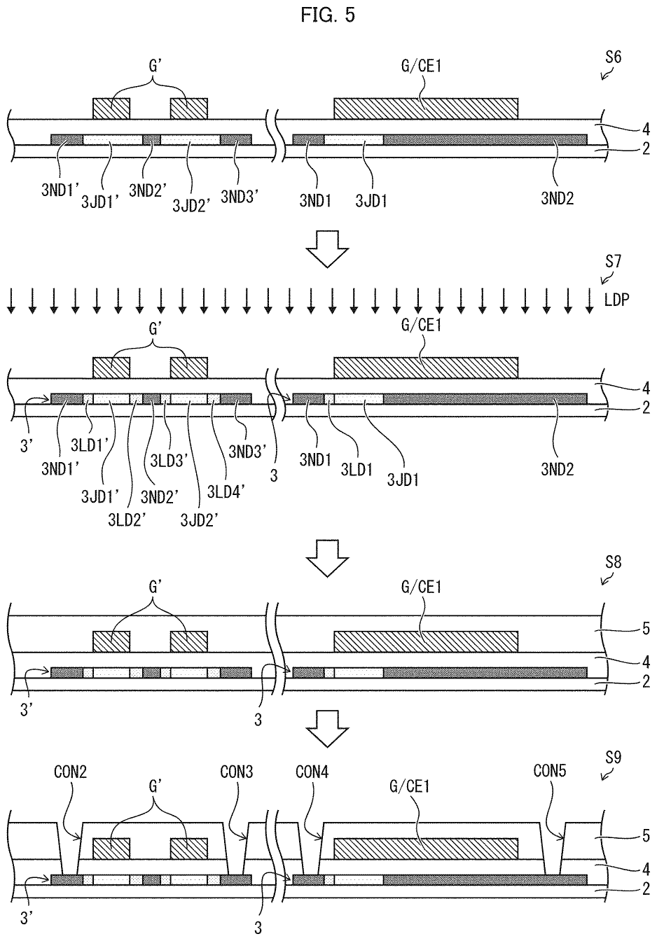

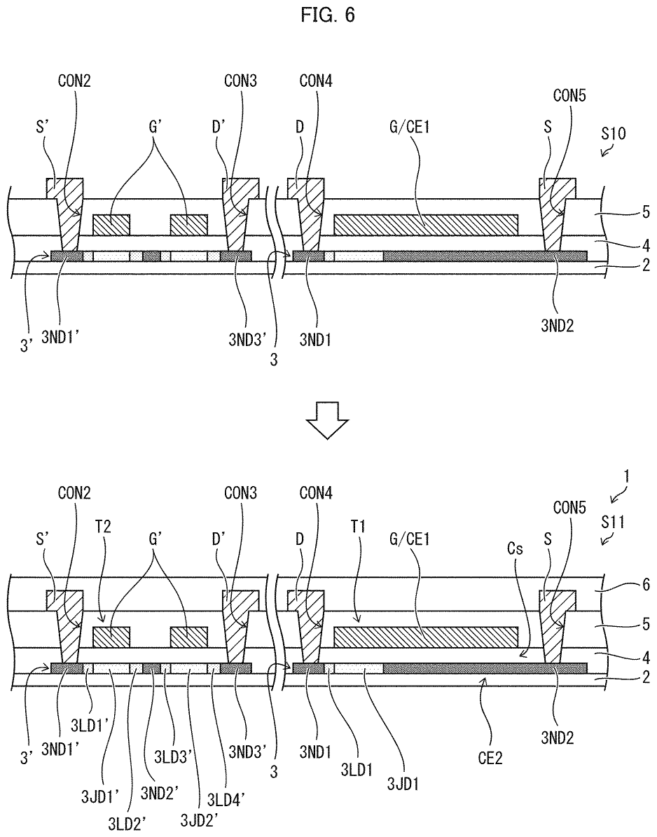

FIG. 4 is a view illustrating some of steps in a manufacturing method of the drive circuit substrate 1 according to the first embodiment. FIG. 5 is a view illustrating another some of steps in the manufacturing method of the drive circuit substrate 1 according to the first embodiment. FIG. 6 is a view illustrating still another some of steps in the manufacturing method of the drive circuit substrate 1 according to the first embodiment.

A first step of forming the first semiconductor layer 3 having an island shape included in the first transistor T1 provided with the holding capacitor Cs including the first counter electrode CE1 and the second counter electrode CE2 is S1 step and S2 step illustrated in FIG. 4. In S1 step, first, an amorphous silicon layer is formed on the barrier layer 2, then annealing (heat treatment) for dehydrogenation is performed at, for example, 450° C., and then treatment is performed with an excimer laser at a relatively low temperature, and thus a polysilicon film PS formed at a low temperature can be obtained. In S2 step, the polysilicon film PS is etched using a resist film, and thus the first semiconductor layer 3 having an island shape constituted by the first channel region 3JD1 containing no impurity can be obtained.

A second step of forming the first insulating layer 4 on the first semiconductor layer 3 is S3 step illustrated in FIG. 4. In S3 step, annealing (heat treatment) is performed after film formation, and thus the first insulating layer 4 can be obtained.

A third step of forming a resist film RM having a predetermined shape on the first insulating layer 4 and injecting an impurity into a part of the first semiconductor layer 3 by using the resist film RM as a mask and thus forming the first channel region 3JD1, and the first source region 3ND2 and the first drain region 3ND1 each having an impurity concentration higher than that of the first channel region 3JD1 is S4 step illustrated in FIG. 4. That is, in S4 step, HDP of injecting a high concentration impurity is performed by using the resist film RM as a mask, and thus the first channel region 3JD1 which is protected by the resist film RM and thus contains no impurity, and the first source region 3ND2 and the first drain region 3ND1 each having an impurity concentration higher than that of the first channel 1 region 3JD1 and containing a high concentration impurity are formed.

The step of removing the resist film RM is S5 step illustrated in FIG. 4, and in S5 step illustrated in FIG. 4, the resist film RM can be removed using a solvent for peeling off the resist film RM.

A fourth step of forming the first gate electrode G-cum-second counter electrode CE1 on the first insulating layer 4 so as to overlap the first channel region 3JD1 and a part of the first source region 3ND2 serving as the first counter electrode CE2 in a plan view after removing the resist film RM is S6 step illustrated in FIG. 5. In the present embodiment, a case will be described as an example in which the first gate electrode G-cum-second counter electrode CE1 is provided so as not to overlap a part of the first channel region 3JD1 on the first drain region 3ND1 side in a plan view in S6 step. However, no such limitation is intended, and the first gate electrode G-cum-second counter electrode CE1 may be formed so as to overlap the entire first channel region 3JD1 in a plan view.

A fifth step of forming the first drain electrode D electrically connected to the first drain region 3ND1 and the first source electrode S electrically connected to the first source region 3ND2 is S9 step illustrated in FIGS. 5 and S10 step illustrated in FIG. 6. In S9 step, the contact hole CON4 exposing the first drain region 3ND1 and the contact hole CON5 exposing the first source region 3ND2 are formed. In S10 step, the first drain electrode D is electrically connected to the first drain region 3ND1 via the contact hole CON4 exposing the first drain region 3ND1, and the first source electrode S is electrically connected to the first source region 3ND2 via the contact hole CON5 exposing the first source region 3ND2.

According to the manufacturing method of the drive circuit substrate 1 including the first step to the fifth step described above, the drive circuit substrate 1 in which each of the plurality of unit drive circuits DRU includes the first transistor T1 provided with the first gate electrode G-cum-second counter electrode CE1 can be manufactured. Since the first gate electrode G-cum-second counter electrode CE1 is provided, it is not necessary to separately form a contact hole for electrically connecting the first gate electrode G and the second counter electrode CE to each other, and an area of the first transistor T1 can be reduced by not forming the contact hole. Thus, in the drive circuit substrate 1, the unit drive circuit DRU can be made high definition.

In the present embodiment, in the fourth step, that is, S6 step illustrated in FIG. 5, the first gate electrode G-cum-second counter electrode CE1 is formed so as not to overlap a part of the first channel region 3JD1 on the first drain region 3ND1 side in a plan view as described above, and thereafter, that is, between the t fourth step (S6 step illustrated in FIG. 5) and the fifth step (S9 step illustrated in FIGS. 5 and S10 step illustrated in FIG. 6), a step of forming the first low concentration region 3LD1 is performed. The step of forming the first low concentration region 3LD1 is S7 step illustrated in FIG. 5. In S7 step, an impurity is injected into a part of the first semiconductor layer 3 by using the first gate electrode G-cum-second counter electrode CE1 as a mask, and thus the first low concentration region 3LD1 having an impurity concentration lower than that of each of the first source region 3ND2 and the first drain region 3ND1 and having an impurity concentration higher than that of the first channel region 3JD1 is formed. That is, in S7 step, LDP of injecting a low concentration impurity is performed by using the first gate electrode G-cm-second counter electrode CE1 as a mask, and thus the first low concentration region 3LD1 can be formed in a part of the first channel region 3JD1 which is not protected by the first gate electrode G-cum-second counter electrode CE1. Since each of the first source region 3ND2 and the first drain region 3ND1 already contains the high concentration impurity, even when the LDP of injecting the low concentration impurity is performed, the first source region 3ND2 and the first drain region 3ND1 remain as regions each containing the high concentration impurity. When electrons as carriers accelerated by obtaining high kinetic energy reach the first low concentration region 3LD1 which is immediately before the drain and a low concentration portion of the impurity, the electrons are decelerated and their momentum is reduced, so that the electrons can be suppressed from entering the first gate electrode G-cum-second counter electrode CE1.

In the present embodiment, in the above-described first step, that is, S1 step and S2 step illustrated in FIG. 4, the second semiconductor layer having an island shape including the second channel regions 3JD1′ and 3JD2′ included in the second transistor T2 is formed together with the first semiconductor layer including the first channel region 3JD1. Then, in the above-described second step, that is, S3 step illustrated in FIG. 4, the first insulating layer 4 is formed on the first semiconductor layer including the first channel region 3JD1 and the second semiconductor layer including the second channel regions 3JD1′ and 3JD2′. Then in the above-described third step, that is, S4 step illustrated in FIG. 4, the resist film RM is also formed on the first insulating layer 4 provided on the second semiconductor layer 3′ and an impurity is injected into a part of the second semiconductor layer 3′ by using the resist film RM as a mask, and thus the second channel regions 3JD1′ and 3JD2′ and the second source region 3ND1′ and the second drain region 3ND3′ each having an impurity concentration higher than that of the second channel regions 3JD1′ and 3JD2′ were formed. Further, in the above-described fourth step, that is, S6 step illustrated in FIG. 5, the second gate electrode G′ is formed on the first insulating layer 4 so as to overlap the second channel regions 3JD1′ and 3JD2′ in a plan view. In the fifth step, that is, S9 step illustrated in FIGS. 5 and S10 step illustrated in FIG. 6, the second drain electrode D′ electrically connected to the second drain region 3ND3′ and the first gate electrode G-cum-second counter electrode CE1, the second source electrode S′ electrically connected to the second source region 3ND1′, the first drain electrode D, and the first source electrode S are formed of the same material as the same layer. As described above, the drive circuit substrate 1 provided with the plurality of unit drive circuits DRU each including the first transistor T1 and the second transistor T2 can be achieved.

S8 step illustrated in FIG. 5 is a step of forming the second insulating layer 5, and the second insulating layer 5 can be obtained by performing activation annealing (heat treatment) after the film formation. In the above-described fifth step, that is, S9 step illustrated in FIGS. 5 and S10 step illustrated in FIG. 6, the contact holes CON2 to CON5 are formed in the first insulating layer 4 and the second insulating layer 5 so as to expose the first source region 3ND2, the first drain region 3ND1, the second source region 3ND1′, and the second drain region 3ND3′, and then the first source electrode S, the first drain electrode D, the second source electrode S′, and the second drain electrode D′ electrically connected to the first source region 3ND2, the first drain region 3ND1, the second source region 3ND1′, and the second drain region 3ND3′, respectively, via the contact holes CON2 to CON5 are formed. In the step of forming the first source electrode S, the first drain electrode D, the second source electrode S′, and the second drain electrode D′, each of the first source electrode S, the first drain electrode D, the second source electrode S′, and the second drain electrode D′ can be formed in a predetermined shape by etching using a resist film. S11 step illustrated in FIG. 6 is a step of forming the passivation film 6.

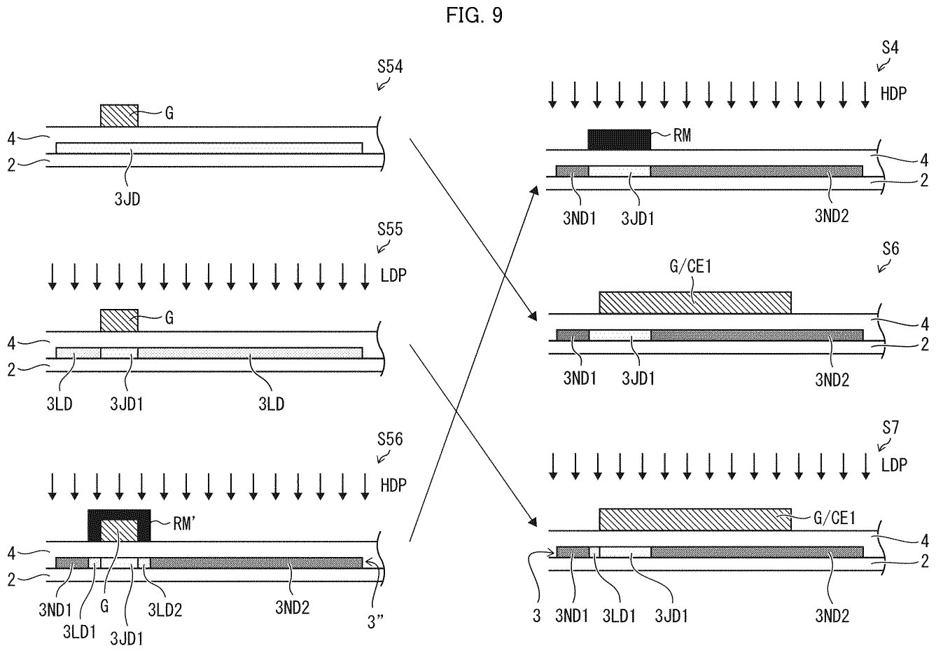

FIG. 7 is a plan view of a drive circuit substrate 50 according to the first comparative example and is a view illustrating a schematic configuration of the drive circuit substrate 50. Note that, in FIG. 7, a barrier layer 2, a first insulating layer 4, a second insulating layer 5, and a passivation film 6 are not illustrated. FIG. 8 is a cross-sectional view illustrating a schematic configuration of the drive circuit substrate 50 according to the first comparative example. FIG. 8 is a cross-sectional view of the drive circuit substrate 50 taken along line X3-X3′ and line X4-X4′ illustrated in FIG. 7. FIG. 9 is a diagram illustrating a difference between the order of some of steps in the manufacturing method of the drive circuit substrate 1 according to the first embodiment and the order of some of steps in the manufacturing method of the drive circuit substrate 50 according to the first comparative example.

As illustrated in FIGS. 7 and 8, in the case of the first transistor T1′ provided on the drive circuit substrate 50 of the first comparative example, the gate electrode G and the second counter electrode CEL are provided as different layers. Thus, in the drive circuit substrate 50, it is necessary to provide the contact holes CON8 and CON9 for electrically connecting the gate electrode G and the second counter electrode CE1 to each other in the second insulating layer 5. As described above, a formation area of the first transistor T1′ provided on the drive circuit substrate 50 of the first comparative example provided with the contact holes CON8 and CON9, which are unnecessary in the case of the drive circuit substrate 1 of the first embodiment, becomes larger than a formation area of the first transistor T1 provided on the drive circuit substrate 1 of the first embodiment. Thus, in the drive circuit substrate 50 of the first comparative example, it is difficult to make the unit drive circuit DRU high definition as compared with the drive circuit substrate 1 of the first embodiment. In the case of the first transistor T1′ provided on the drive circuit substrate 50 of the first comparative example, the first low concentration region 3LD1 is provided on the drain side, and the first low concentration region 3LD2 is also provided on the source side.

As illustrated in FIG. 9, in the manufacturing method of the drive circuit substrate 50 of the first comparative example, a step of forming the first gate electrode G (S54 step), a step of performing LDP of injecting the low concentration impurity into the semiconductor layer 3′ by using the first gate electrode G as a mask to form a low concentration region 3LD (S55 step), and a step of performing HDP of injecting the high concentration impurity into the semiconductor layer 3″ by using the resist film RM′ as a mask to form the first source region 3ND2 and the first drain region 3ND1 (S56 step) are performed in this order. On the other hand, in the manufacturing method of the drive circuit substrate 1 of the first embodiment, after S4 step illustrated in FIG. 4 corresponding to S56 step is performed first, S6 step illustrated in FIG. 5 corresponding to S54 step and S7 step illustrated in FIG. 5 corresponding to S55 step are performed in this order.

As described above, according to the manufacturing method of the drive circuit substrate 1 of the first embodiment, the manufacturing method of the drive circuit substrate 1 that can make the unit drive circuit DRU high definition can be achieved only by changing a part of a step order in the manufacturing method of the drive circuit substrate 50 of the first comparative example.

### Second Embodiment

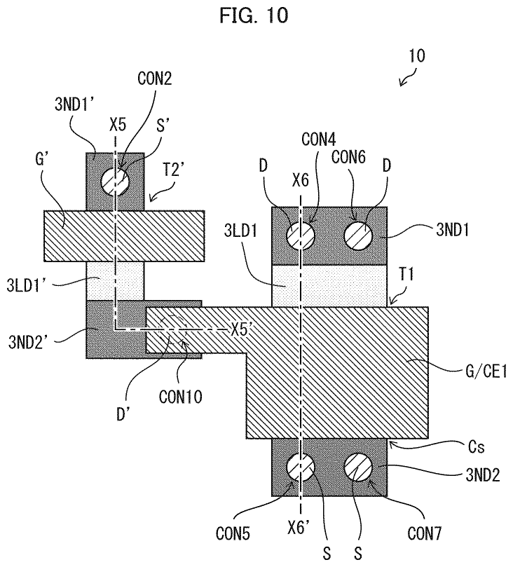

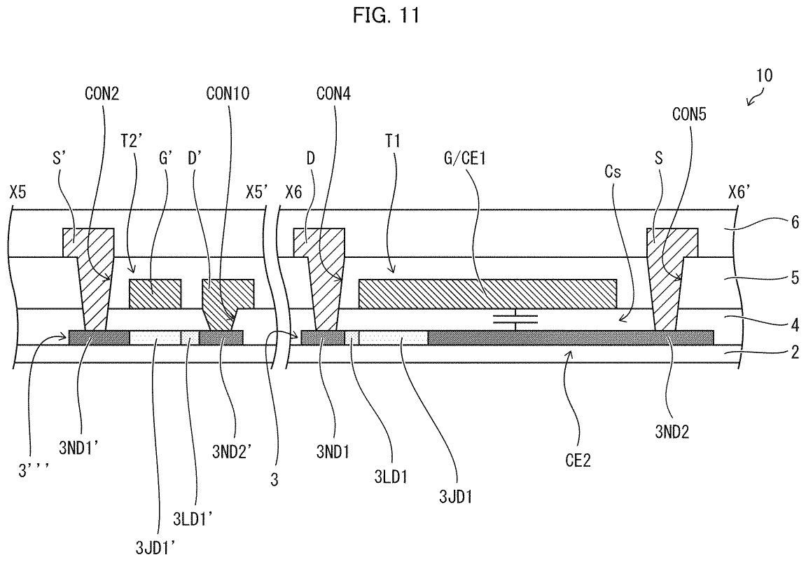

FIG. 10 is a plan view of a drive circuit substrate 10 according to a second embodiment, and is a plan view illustrating a schematic configuration of the drive circuit substrate 10. Note that, in FIG. 10, a barrier layer 2, a first insulating layer 4, a second insulating layer 5, and a passivation film 6 are not illustrated. FIG. 11 is a cross-sectional view illustrating the schematic configuration of the drive circuit substrate 10 according to the second embodiment. FIG. 11 is a cross-sectional view of the drive circuit substrate 10 taken along line X5-X5′ and line X6-X6′ illustrated in FIG. 10.

As illustrated in FIGS. 10 and 11, each of the plurality of unit drive circuits DRU provided on the drive circuit substrate 10 according to the second embodiment includes a first transistor T1 and a second transistor T2′ serving as a single-gate transistor. A configuration of the second transistor T2′ is different from a configuration of the second transistor T2 in the first embodiment described above. The second drain electrode D′ provided in the second transistor T2′ is electrically connected to the second drain region 3ND2′ via a contact hole CON10 provided in the first insulating layer 4, and the second drain electrode D′ is made of the same material as the first gate electrode G-cum-second counter electrode CE1 as the same layer as the first gate electrode G-cum-second counter electrode CE1.

In the case of the drive circuit substrate 1 illustrated in FIG. 2 described in the first embodiment and the drive circuit substrate 50 of the first comparative example illustrated in FIG. 7, since the second drain electrode D′ and the first gate electrode G-cum-second counter electrode CE1 are formed as different layers, it is necessary to provide the contact hole CON1 for electrically connecting the second drain electrode D′ and the first gate electrode G-cum-second counter electrode CE1 to each other in the second insulating layer 5. On the other hand, according to the drive circuit substrate 10 of the second embodiment, since the second drain electrode D′ is made of the same material as the first gate electrode G-cum-second counter electrode CE1 as the same layer as the first gate electrode G-cum-second counter electrode CE1, it is not necessary to separately provide a contact hole for electrically connecting the second drain electrode D′ and the first gate electrode G-cum-second counter electrode CE1 to each other, and the formation areas of the first transistor T1 and the second transistor T2′ can be reduced in the unit drive circuit DRU of the drive circuit substrate 10. Thus, the drive circuit substrate 10 that can make the unit drive circuit DRU high definition can be achieved.

As illustrated in FIGS. 10 and 11, the second semiconductor layer 3′″ provided in the second transistor T2′ includes the second low concentration region 3LD1′ provided between the second drain region 3ND2′ and the second channel region 3JD1′, the second low concentration region 3LD1′ contains an impurity and has an impurity concentration lower than that of each of the second source region 3ND1′ and the second drain region 3ND2′, and each of the second gate electrode G′ and the second drain electrode D′ does not overlap the second low concentration region 3LD1′ in a plan view. When the second transistor T2′ is provided with the low concentration region LDD for the purpose of reducing the leakage current during off time, the same function can be maintained even when the low concentration region LDD is provided only on the drain side. Thus, in the present embodiment, the second low concentration region 3LD1′ is provided only on the drain side in the second semiconductor layer 3″ provided in the second transistor T2′. Thus, when electrons as carriers accelerated by obtaining high kinetic energy reach the second low concentration region 3LD1′ which is immediately before the drain and a low concentration portion of the impurity, the electrons are decelerated and their momentum is reduced, so that the electrons can be prevented from entering the second gate electrode G′ without increasing the formation area of the second transistor T2′.

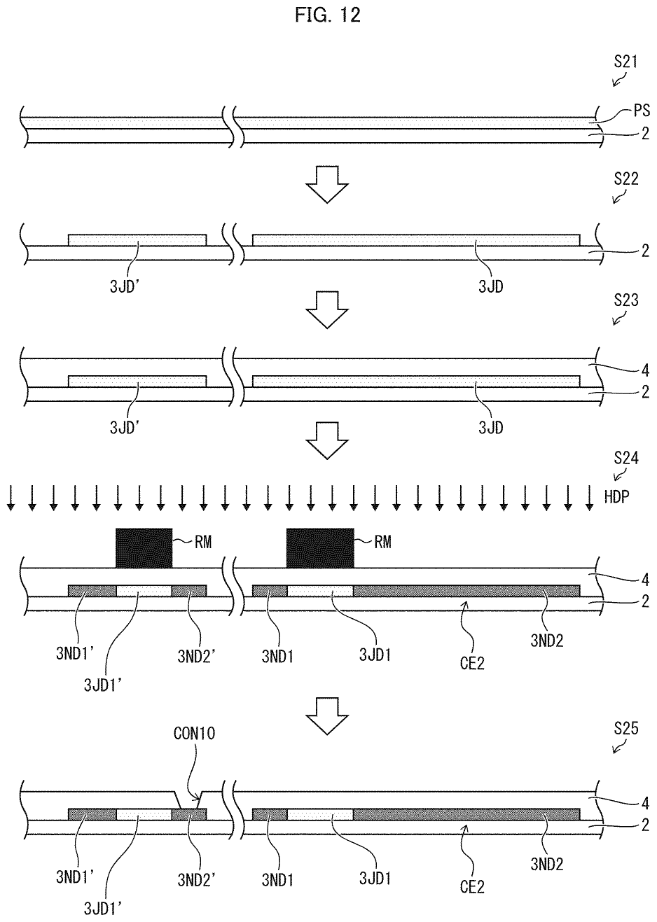

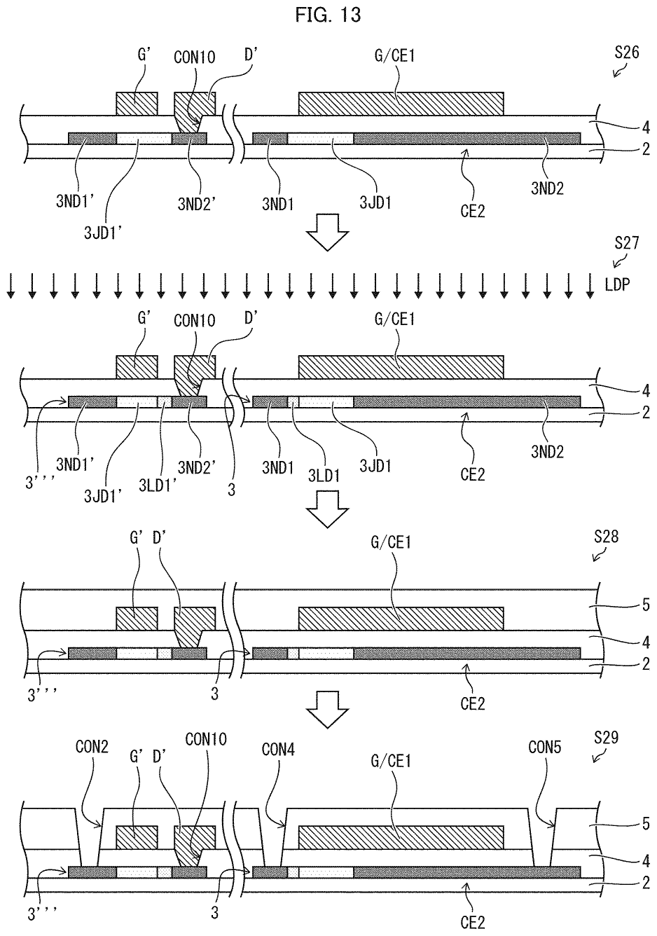

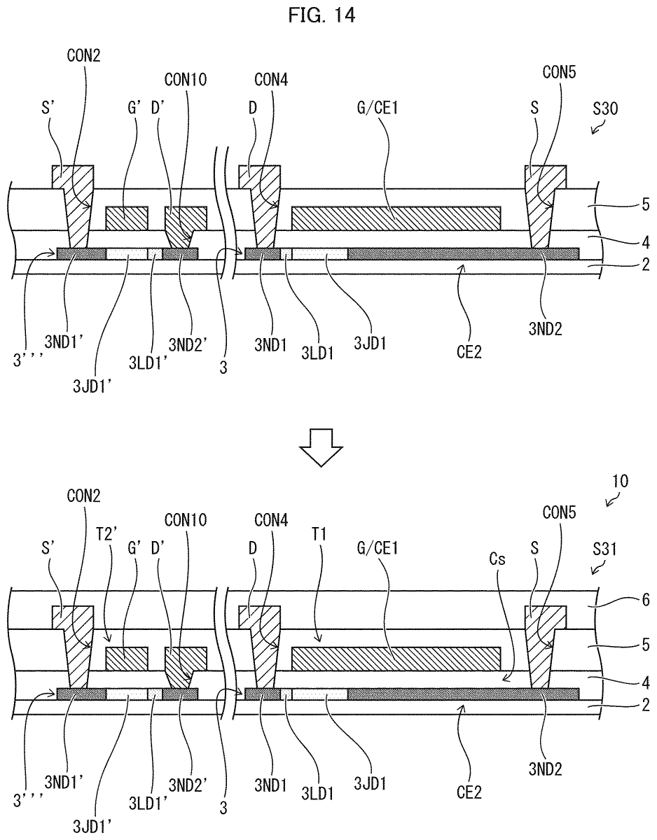

FIG. 12 is a view illustrating some of steps in a manufacturing method of the drive circuit substrate 10 according to the second embodiment. FIG. 13 is a view illustrating another some of steps in the manufacturing method of the drive circuit substrate 10 according to the second embodiment. FIG. 14 is a view illustrating still another some of steps in the manufacturing method of the drive circuit substrate 10 according to the second embodiment.

Since S21 step, S22 step, S23 step, and S24 step illustrated in FIG. 12 are the same as S1 step, S2 step, S3 step, and S4 step, respectively, illustrated in FIG. 4 in the first embodiment described above, the description thereof is omitted here.

In the present embodiment, in the above-described first step, that is, S21 step and S22 step illustrated in FIG. 12, the second semiconductor layer having an island shape including the second channel region 3JD1′ included in the second transistor T2 is formed together with the first semiconductor layer including the first channel region 3JD1. Then, in the above-described second step, that is, S23 step illustrated in FIG. 12, the first insulating layer 4 is formed on the first semiconductor layer including the first channel region 3JD1 and the second semiconductor layer including the second channel region 3JD1′. Then, in the above-described third step, that is, S24 step illustrated in FIG. 12, the resist film RM is also formed on the first insulating layer 4 provided on the second semiconductor layer 3′ and an impurity is injected into a part of the second semiconductor layer 3′ by using the resist film RM as a mask, and thus the second channel region 3JD1′, and the second source region 3ND1′ and the second drain region 3ND2′ each having an impurity concentration higher than that of the second channel region 3JD1′ are formed. Further, in the step of forming the contact hole CON10 performed between the above-described third step and the above-described fourth step, that is, S25 step illustrated in FIG. 12, the contact hole CON10 is formed in the first insulating layer 4 so as to overlap the second drain region 3ND2′ in a plan view. Then, in the above-described fourth step, that is, S26 step illustrated in FIG. 12, the second gate electrode G′ made of the same material as the first gate electrode G-cum-second counter electrode CE1 in the same layer as the first gate electrode G-cum-second counter electrode CE1 is formed on the first insulating layer 4 so as to overlap the second channel region 3JD1′ in a plan view, and the second drain electrode D′ electrically connected to the second drain region 3ND2′ via the contact hole CON10 is formed. In the above-described fifth step, that is, S29 step and S30 step illustrated in FIG. 12, the second source electrode S′ electrically connected to the second source region 3ND1′, the first drain electrode D electrically connected to the first drain region 3ND1, and the first source electrode S electrically connected to the first source region 3ND2 are made of the same material as the same layer.

In the present embodiment, in the step of forming the first low concentration region 3LD1 performed between the above-described fourth step and the fifth step, that is, S27 step illustrated in FIG. 13, an impurity is injected into a part of the second semiconductor layer 3′″ by using the second gate electrode G′ and the second drain electrode D′ as masks, and thus the second low concentration region 3LD1′ having an impurity concentration lower than that of each of the second source region 3ND1′ and the second drain region 3ND2′ and having an impurity concentration higher than that of the second channel region 3JD1′ is formed. That is, in S27 step, LDP of injecting the low concentration impurity is performed by using the second gate electrode G′ and the second drain electrode D′ as masks, and thus the second low concentration region 3JD1′ can be formed in a part of the second channel region 3LD1′ which is not protected by the second gate electrode G′ and the second drain electrode D′. Since each of the second source region 3ND1′ and the second drain region 3ND2′ already contains the high concentration impurity, even when the LDP of injecting the low concentration impurity is performed, the second source region 3ND1′ and the second drain region 3ND2′ remain as regions each containing the high concentration impurity. S28 step illustrated in FIG. 13 is a step of forming the second insulating layer 5, and the second insulating layer 5 can be obtained by performing activation annealing (heat treatment) after the film formation. S31 step illustrated in FIG. 14 is a step of forming the passivation film 6.

### Third Embodiment

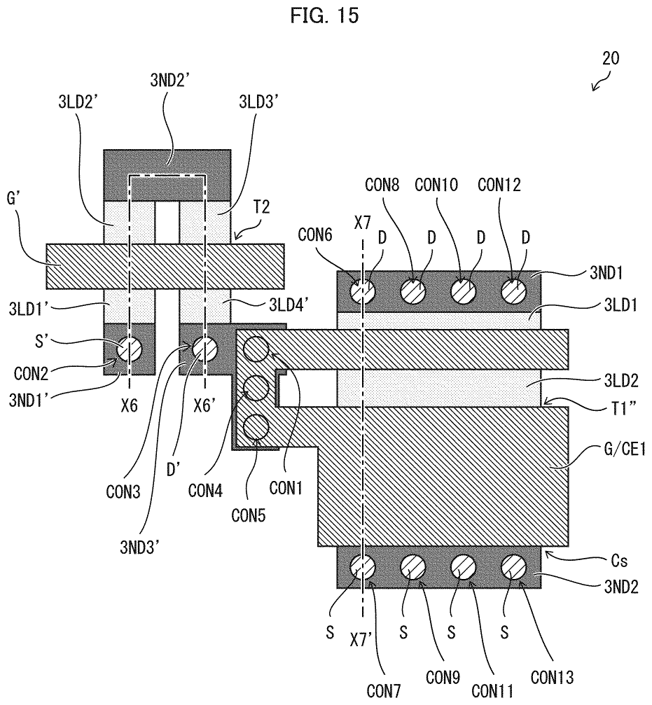

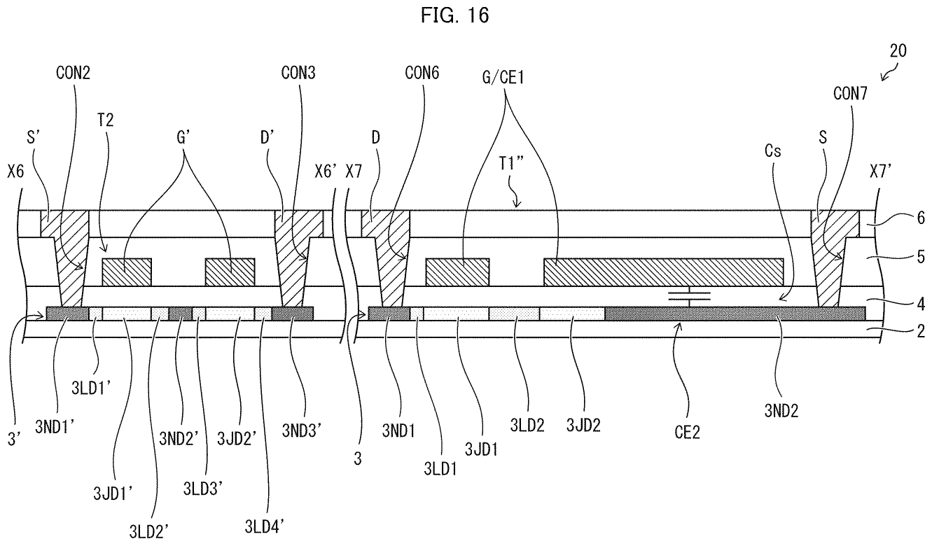

FIG. 15 is a plan view illustrating a schematic configuration of a drive circuit substrate 20 according to the third embodiment. Note that, in FIG. 15, a barrier layer 2, a first insulating layer 4, a second insulating layer 5, and a passivation film 6 are not illustrated. FIG. 16 is a cross-sectional view illustrating the schematic configuration of the drive circuit substrate 20 according to the third embodiment. FIG. 16 is a cross-sectional view of the drive circuit substrate 20 taken along line X6-X6′ and line X7-X7′ illustrated in FIG. 15.

In the present embodiment, the drive circuit substrate 20 illustrated in FIGS. 15 and 16 is different from the drive circuit substrate 1 according to the first embodiment, which includes the first transistor T1 (single-gate the second transistor transistor) and T2 (double-gate transistor) and which is illustrated in FIGS. 2 and 3, and the drive circuit substrate 10 according to the second embodiment, which includes the first transistor T1 (single-gate transistor) and the second transistor T2′ (single-gate transistor) and which is illustrated in FIGS. 10 and 11, in that the drive circuit substrate 20 includes a first transistor T1″ (double-gate transistor) and a second transistor T2 (a double-gate transistor). The use of a double-gate transistor as an example of a transistor having a multi-gate structure in each embodiment of the disclosure is illustrative only and not limiting.

As illustrated in FIGS. 15 and 16, a first semiconductor layer 3 included in the drive circuit substrate 20 includes a first source region 3ND2, a first drain region 3ND1, two first channel regions 3JD1 and 3JD2, which are provided so as to be spaced from each other between the first source region 3ND2 and the first drain region 3ND1, a first low concentration region 3LD1, which is provided between the first drain region 3ND1 and the first channel region 3JD1 that is closer to the first drain region 3ND1 among the two first channel regions 3JD1 and 3JD2, and a first low concentration region 3LD2, which is provided between the first channel region 3JD1 and the first channel region 3JD2. The first low concentration regions 3LD1 and 3LD2 have an impurity concentration lower than that of the first drain region 3ND1. A first gate electrode G-cum-second counter electrode CE1 does not overlap the first low concentration regions 3LD1 and 3LD2 in a plan view. As illustrated in FIG. 15, a second drain electrode D′ need only be electrically connected to a second drain region 3ND3′ and the first gate electrode G-cum-second counter electrode CE1. In the present embodiment, the second drain electrode D′ is provided to contact the second drain region 3ND3′ via a contact hole CON3, and the first gate electrode G-cum-second counter electrode CE1 is provided to contact the second drain region 3ND3′ via contact holes CON1, CON4, and CON5.

The drive circuit substrate 20 including the first transistor T1″ (double-gate transistor) and the second transistor T2 (double-gate transistor) and illustrated in FIGS. 5 and 16 makes it possible to improve electric-current stability. The second transistor T2 included in the drive circuit substrate 20 has been described in the first embodiment, and the manufacturing method of the drive circuit substrate 20 can employ the manufacturing method of the drive circuit substrate 1 described in the first embodiment. Therefore, detailed description thereof is omitted here.

### Fourth Embodiment

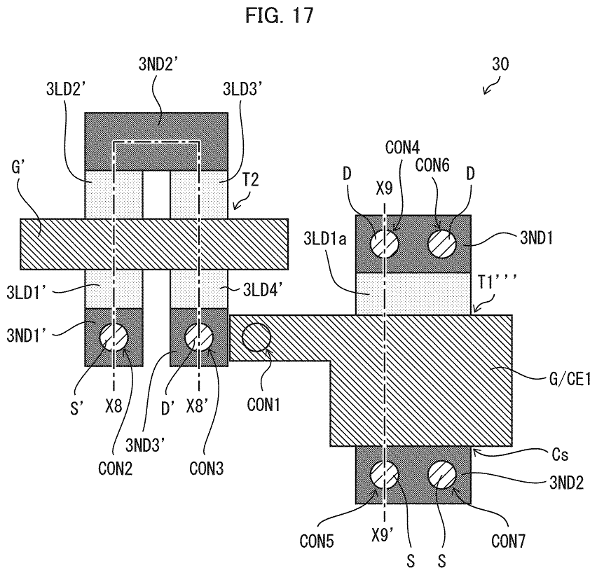

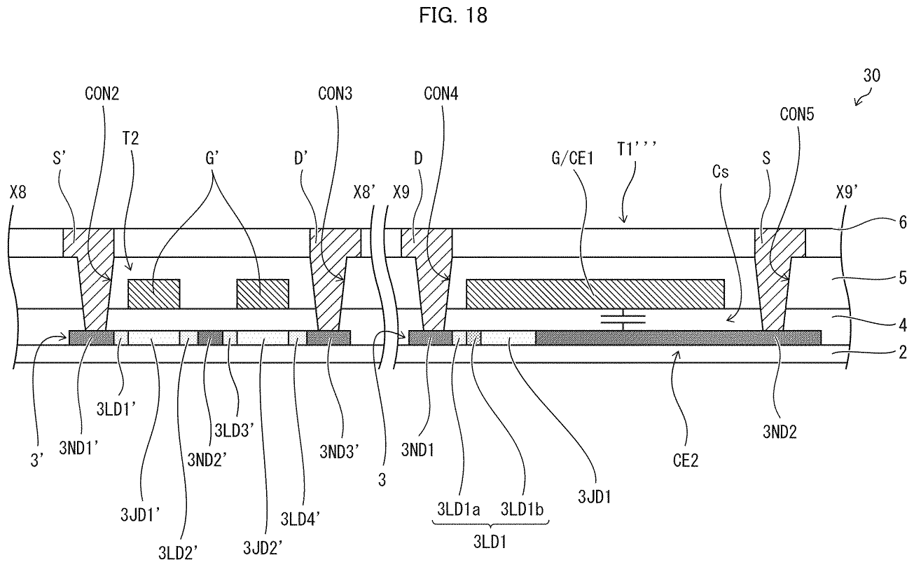

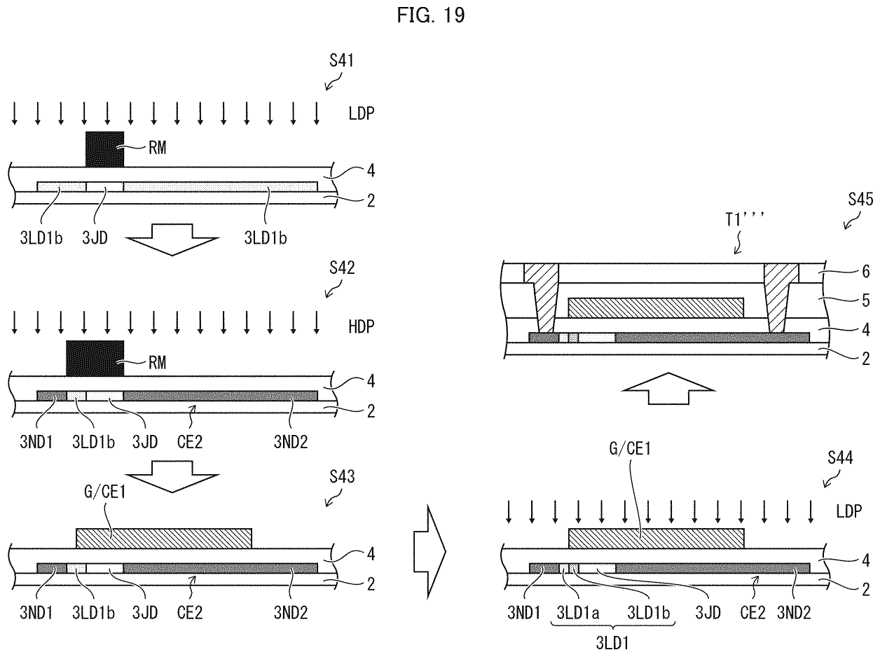

FIG. 17 is a plan view illustrating a schematic configuration of a drive circuit substrate 30 according to the fourth embodiment. Note that, in FIG. 17, a barrier layer 2, a first insulating layer 4, a second insulating layer 5, and a passivation film 6 are not illustrated. FIG. 18 is a cross-sectional view illustrating a schematic configuration of the drive circuit substrate 30 according to the fourth embodiment. FIG. 18 is a cross-sectional view of the drive circuit substrate 30 taken along line X8-X8′ and line X9-X9′ illustrated in FIG. 17. FIG. 19 is a schematic view illustrating a manufacturing method of the drive circuit substrate 30 according to the fourth embodiment.

The drive circuit substrate 30 according to the present embodiment illustrated in FIGS. 17 and 18 is different from the first transistors T1 and T1″ described in the first to third embodiments in that the drive circuit substrate 30 according to the present embodiment includes a first transistor T1′″, which has a first low concentration region 3LD1 including a first region 3LD1b and a second region 3LD1a that is provided closer to a first drain region 3ND1 than is the first region 3LD1b and that has an impurity concentration higher than that of the first region 3LD1b.

As illustrated in FIGS. 17 and 18, a first semiconductor layer 3 included in the drive circuit substrate 30 includes a first channel region 3JD, a first source region 3ND2, the first drain region 3ND1, and a first low concentration region 3LD1 provided between the first drain region 3ND1 and the first channel region 3JD. The first low concentration region 3LD1 has an impurity concentration lower than that of the first drain region 3ND1. The first low concentration region 3LD1 includes the first region 3LD1b and the second region 3LD1a, which is provided closer to the first drain region 3ND1 than is the first region 3LD1b. The second region 3LD1a has an impurity concentration higher than that of the first region 3LD1b. In a plan view, a first gate electrode G-cum-second counter electrode CE1 overlaps the first region 3LD1b and does not overlap the second region 3LD1a.

As illustrated in FIG. 19, the manufacturing method of the drive circuit substrate 30 includes S41 step illustrated in FIGS. 19 and S42 step illustrated in FIG. 19, which are the steps of forming a resist film RM having a predetermined shape on the first insulating layer 4 and injecting an impurity into a part of the first semiconductor layer 4 with the resist film RM as a mask and thus forming the first channel region 3JD and forming the first source region 3ND2 and the first drain region 3ND1 each having an impurity concentration higher than that of the first channel region 3JD.

In S41 step illustrated in FIG. 19, LDP of injecting a low concentration impurity into a part of the first semiconductor layer 3 with the resist film (first resist film) RM serving as a mask is performed, and thus the first channel region 3JD and the first region 3LD1b of the first low concentration region 3LD1 having an impurity concentration higher than that of the first channel region 3JD is formed.

In S42 step illustrated in FIG. 19, after removal of the resist film (first resist film) RM, HDP of injecting a high concentration impurity into a part of the first semiconductor layer 3 is performed with, as a mask, a resist film (second resist film) RM, which is provided so as to overlap, in a plan view, the first channel region 3JD and a part of the first region 3LD1b of the first low concentration region 3LD1 in contact with the first channel region 3JD, and thus the first source region 3ND2 and the first drain region 3ND1 which have an impurity concentration higher than those of the first channel region 3JD and of the first region 3LD1b of the first low concentration region 3LD1 are formed.

In S43 step illustrated in FIG. 19, which is the step of forming the first gate electrode G-cum-second counter electrode CE1, after removal of the resist film (second resist film) RM, a first gate electrode G-cum-second counter electrode CE1 is formed on the first insulating layer 4 so as to overlap, in a plan view, a part of the first region 3LD1b of the first low concentration region 3LD1 in contact with the first channel region 3JD, the first channel region 3JD, and a part of the first source region 3ND2, which is a first counter electrode CE2.

S44 step illustrated in FIG. 19 is the step of forming the second region 3LD1a of the first low concentration region 3LD1. The step of forming the second region 3LD1a of the first low concentration region 3LD1 (S44 step illustrated in FIG. 19) is performed between S43 step illustrated in FIG. 19 (the step of forming the first gate electrode G-cum-second counter electrode CE1) and the step of forming a first drain electrode D electrically connected to the first drain region 3ND1 and a first source electrode S electrically connected to the first source region 3ND2, which is a part of S45 step illustrated in FIG. 19. The step of forming the second region 3LD1a of the first low concentration region 3LD1 (S44 step illustrated in FIG. 19) is the step of performing LDP of injecting a low concentration impurity into a part of the first semiconductor layer 3 with the first gate electrode G-cum-second counter electrode CE1 as a mask, and thus forming the second region 3LD1a of the first low concentration region 3LD1, which has an impurity concentration lower than those of the first source region 3ND2 and the first drain region 3ND1 and higher than that of the first region 3LD1b of the first low concentration region 3LD1.

As described above, the drive circuit substrate 30 according to the present embodiment includes a first transistor T1′″, which has a first low concentration region 3LD1 including a first region 3LD1b and a second region 3LD1a that is provided closer to a first drain region 3ND1 than is the first region 3LD1b and that has an impurity concentration higher than that of the first region 3LD1b. The first gate electrode G-cum-second counter electrode CE1 included in the first transistor T1′″ overlaps the first region 3LD1b in a plan view. This gives the first transistor T1′″ a gate-overlapped LDD (GOLD) structure. The first transistor T1′″, which has such a gate-overlapped LDD (GOLD) structure, makes it possible to further improve reliability and suppress a decrease in the amount of current while the transistor is on (Ion), in comparison with the first transistors T1 and T1″, which has a lightly doped drain (LDD) structure. Accordingly, the drive circuit substrate 30 including the first transistor T1′″ can supply a large current without increasing the substrate size and achieve a high level of reliability.

### CROSS-REFERENCE TO RELATED APPLICATIONS

This application claims the benefit of priority to Japanese Patent Application Number 2025-022666 filed on Feb. 14, 2025. The entire contents of the above-identified application are hereby incorporated by reference.

### INDUSTRIAL APPLICABILITY

The disclosure can be utilized for a drive circuit substrate and a manufacturing method of the drive circuit substrate.

### REFERENCE SIGNS LIST

1, 10, 20, 30 Drive circuit substrate
3, 3″ First semiconductor layer
3′, 3′″ Second semiconductor layer
4 First insulating layer
5 Second insulating layer
6 Passivation film
3JD1, 3JD2 First channel region
3JD1′, 3JD2′ Second channel region
3ND2 First source region
3ND1 First drain region
3LD1, 3LD2 First low concentration region
3LD1a Second region of first low concentration region
3LD1b First region of first low concentration region
3ND1′ Second source region
3ND3′ Second drain region
3ND2′ High concentration region
3LD1′ to 3LD4′ Second low concentration region
T1, T1″, T1′″ First transistor
T2, T2′ Second transistor
Cs Holding capacitor
S First source electrode
D First drain electrode
G First gate electrode
S′ Second source electrode
′ Second drain electrode
G′ Second gate electrode
CE2 First counter electrode
CE1 Second counter electrode
DRU Unit drive circuit
CON1 to CON12 Contact hole

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A drive circuit substrate comprising:
a first transistor including
a first semiconductor layer having an island shape including a first channel region, and a first source region and a first drain region each containing an impurity,
a first insulating layer provided on the first semiconductor layer,
a first gate electrode-cum-second counter electrode provided on the first insulating layer to overlap the first channel region and a part of the first source region serving as a first counter electrode in a plan view,
a first drain electrode electrically connected to the first drain region,
a first source electrode electrically connected to the first source region, and
a holding capacitor including the first counter electrode and the second counter electrode
wherein the drive circuit substrate includes a plurality of unit drive circuits each including the first transistor.

2. The drive circuit substrate according to claim 1,
wherein the first semiconductor layer includes the first channel region, the first source region, the first drain region, and a first low concentration region provided between the first drain region and the first channel region,
the first low concentration region has an impurity concentration lower than an impurity concentration of the first drain region, and
the first gate electrode-cum-second counter electrode does not overlap the first low concentration region in a plan view.

3. The drive circuit substrate according to claim 1,
wherein the first channel region includes two first channel regions, which are provided so as to be spaced from each other between the first source region and the first drain region,
the first semiconductor layer includes the first source region, the first drain region, the two first channel regions, and first low concentration regions, one of which is provided between the two first channel regions and the other of which is provided between the first drain region and one of the two first channel regions which is closer to the first drain region than the other,
the first low concentration regions have an impurity concentration lower than an impurity concentration of the first drain region, and
the first gate electrode-cum-second counter electrode does not overlap the first low concentration regions in a plan view.

4. The drive circuit substrate according to claim 1,
wherein the first semiconductor layer includes the first channel region, the first source region, the first drain region, and a first low concentration region provided between the first drain region and the first channel region,
the first low concentration region has an impurity concentration lower than an impurity concentration of the first drain region,
the first low concentration region includes a first region and a second region, which is provided closer to the first drain region than is the first region,
the second region has an impurity concentration higher than an impurity concentration of the first region, and
the first gate electrode-cum-second counter electrode overlaps the first region and does not overlap the second region in a plan view.

5. The drive circuit substrate according to claim 1,
wherein each of the plurality of unit drive circuits includes a second transistor,
the second transistor includes
a second semiconductor layer having an island shape including a second channel region, and a second source region and a second drain region each containing the impurity,
the first insulating layer provided on the second semiconductor layer,
a second gate electrode provided on the first insulating layer to overlap the second channel region in a plan view,
a second drain electrode electrically connected to the second drain region and the first gate electrode-cum-second counter electrode, and
a second source electrode electrically connected to the second source region.

6. The drive circuit substrate according to claim 5,
wherein the second drain electrode is electrically connected to the second drain region via a contact hole provided in the first insulating layer, and
the second drain electrode is made of the same material as the first gate electrode-cum-second counter electrode as the same layer as the first gate electrode-cum-second counter electrode.

7. The drive circuit substrate according to claim 6,
wherein the second semiconductor layer includes a second low concentration region provided between the second drain region and the second channel region,
the second low concentration region has an impurity concentration lower than an impurity concentration of the second drain region, and
each of the second gate electrode and the second drain electrode does not overlap the second low concentration region in a plan view.

8. A manufacturing method of a drive circuit substrate, the manufacturing method comprising:
forming a first semiconductor layer having an island shape included in a first transistor provided with a holding capacitor including a first counter electrode and a second counter electrode;
forming a first insulating layer on the first semiconductor layer;
forming a first channel region, and a first source region and a first drain region each having an impurity concentration higher than an impurity concentration of the first channel region by forming a resist film having a predetermined shape on the first insulating layer and injecting an impurity into a part of the first semiconductor layer by using the resist film as a mask;
forming a first gate electrode-cum-second counter electrode on the first insulating layer to overlap the first channel region and a part of the first source region serving as the first counter electrode in a plan view after removing the resist film; and
forming a first drain electrode electrically connected to the first drain region and a first source electrode electrically connected to the first source region,
wherein in the manufacturing method, a plurality of unit drive circuits including the first transistor are formed.

9. The manufacturing method of a drive circuit substrate according to claim 8,
wherein in the formation of the first gate electrode-cum-second counter electrode, the first gate electrode-cum-second counter electrode is formed not to overlap a part of the first channel region on the first drain region side in a plan view, and
in formation of a first low concentration region performed between the formation of the first gate electrode-cum-second counter electrode and the formation of the first drain electrode and the first source electrode, the first low concentration region having an impurity concentration lower than an impurity concentration of each of the first source region and the first drain region and having an impurity concentration higher than an impurity concentration of the first channel region is formed by injecting the impurity into a part of the first semiconductor layer by using the first gate electrode-cum-second counter electrode as a mask.

10. The manufacturing of a drive circuit substrate according to claim 8,
wherein in the formation of the first semiconductor layer, a second semiconductor layer having an island shape included in a second transistor is formed together with the first semiconductor layer,
in the formation of the first insulating layer, the first insulating layer is formed on the first semiconductor layer and the second semiconductor layer,
in the formation of the first channel region, and the first source region and the first drain region, a second channel region, and a second source region and a second drain region having an impurity concentration higher than an impurity concentration of the second channel region are formed by also forming the resist film on the first insulating layer provided on the second semiconductor layer and injecting the impurity into a part of the second semiconductor layer by using the resist film as a mask,
in the formation of the first gate electrode-cum-second counter electrode, a second gate electrode is formed on the first insulating layer to overlap the second channel region in a plan view,
in the formation of the first drain electrode and the first source electrode, a second drain electrode electrically connected to the second drain region and the first gate electrode-cum-second counter electrode, a second source electrode electrically connected to the second source region, the first drain electrode, and the first source electrode are formed of the same material as the same layer, and
the plurality of unit drive circuits including the first transistor and the second transistor are formed.

11. The manufacturing method of a drive circuit substrate according to claim 9,
wherein in the formation of the first semiconductor layer, a second semiconductor layer having an island shape included in a second transistor is formed together with the first semiconductor layer,
in the formation of the first insulating layer, the first insulating layer is formed on the first semiconductor layer and the second semiconductor layer,
in the formation of the first channel region, and the first source region and the first drain region, a second channel region, and a second source region and a second drain region having an impurity concentration higher than an impurity concentration of the second channel region are formed by also forming the resist film on the first insulating layer provided on the second semiconductor layer and injecting the impurity into a part of the second semiconductor layer by using the resist film as a mask,
in formation of a contact hole performed between the formation of the first channel region, and the first source region and the first drain region and the formation of the first gate electrode-cum-second counter electrode, the contact hole is formed in the first insulating layer to overlap the second drain region in a plan view,
in the formation of the first gate electrode-cum-second counter electrode, a second gate electrode is formed of the same material as the first gate electrode-cum-second counter electrode as the same layer as the first gate electrode-cum-second counter electrode on the first insulating layer to overlap the second channel region in a plan view, and a second drain electrode electrically connected to the second drain region via the contact hole is formed,
in the formation of the first drain electrode and the first source electrode, a second source electrode electrically connected to the second source region, the first drain electrode, and the first source electrode are formed of the same material as the same layer, and
the plurality of unit drive circuits including the first transistor and the second transistor are formed.

12. The manufacturing method of a drive circuit substrate according to claim 11,
wherein in the formation of the first low concentration region performed between the formation of the first gate electrode-cum-second counter electrode and the formation of the first drain electrode and the first source electrode, a second low concentration region an impurity having concentration lower than an impurity concentration of each of the second source region and the second drain region and having an impurity concentration higher than an impurity concentration of the second channel region is formed by injecting the impurity into a part of the second semiconductor layer by using the second gate electrode and the second drain electrode as masks.

13. The manufacturing method of a drive circuit substrate according to claim 8,
wherein in the formation of the first channel region, and the first source region and the first drain region includes:
forming the first channel region and a first region of a first low concentration region having an impurity concentration higher than the than the impurity concentration of the first channel region, by injecting the impurity into the part of the first semiconductor layer by using a first resist film as a mask; and
forming the first source region and the first drain region each having the impurity concentration higher than the impurity concentration of the first channel region and the impurity concentration of the first region of the first low concentration region by, after the first resist film has been removed, injecting the impurity into the part of the first semiconductor layer by using, as a mask, a second resist film, which is provided so as to overlap, in a plan view, the first channel region and a part of the first region of the first low concentration region in contact with the first channel region,
wherein in the formation of the first gate electrode-cum-second counter electrode, after the second resist film has been removed, the first gate electrode-cum-second counter electrode is formed on the first insulating layer so as to overlap, in a plan view, the part of the first region of the first low concentration region in contact with the first channel region, the first channel region, and a part of the first source region, which is the first counter electrode, and
in forming of a second region of the first low concentration region between the formation of the first gate electrode-cum-second counter electrode and the formation of the first drain electrode and the first source electrode, the second region of the first low concentration region having an impurity concentration lower than the impurity concentration of each of the first source region and the first drain region and higher than the impurity concentration of the first region of the first low concentration region is formed by injecting the impurity into the part of the first semiconductor layer by using the first gate electrode-cum-second counter electrode as a mask.
